(19) United States
(12) Patent Application Publication
(10) Pub. No.: US 2024/0142508 A1
(43) Pub. Date: May 2, 2024

(54) ADAPTABLE METHOD FOR PROBLEM IDENTIFICATION AND PREDICTIVE FAILURE ANALYSIS USING ELECTRICAL WAVEFORMS

(71) Applicant: Andrew Schultz, Ocala, FL (US)

(72) Inventor: Andrew Schultz, Ocala, FL (US)

(21) Appl. No.: 18/484,813

(22) Filed: Oct. 11, 2023

Related U.S. Application Data
(60) Provisional application No. 63/379,192, filed on Oct. 12, 2022.

(51) Int. Cl. G01R 31/00

(52) U.S. Cl. CPC G01R 31/005

(57) ABSTRACT

A method and system for the use of artificial intelligence to analyze electrical waveforms to help identify and predict the occurrence of issues with components of both on and off-highway vehicles and equipment. Results of the analysis will be returned to the user providing a possible root cause, and next steps to perform in troubleshooting the issue.

### CROSS REFERENCE TO RELATED APPLICATIONS

This application claims the benefit of U.S. Provisional Patent Application No. 63/379,192, filed Oct. 12, 2022, which is incorporated by reference herein in its entirety.

### STATEMENT RE: FEDERALLY SPONSORED RESEARCH/DEVELOPMENT

Not Applicable.

### FIELD

The present application relates to the use of artificial intelligence to analyze electrical waveforms to identify and predict the occurrence of issues with components of both on and off-highway vehicles and equipment.

### BACKGROUND

The use of waveforms captured by a digital storage oscilloscope to diagnose issues with equipment and machinery is well-known, however interpretation of these data relies upon analysis by a skilled operator. A sufficiently experienced person may be able to recognize anomalies in waveforms based on prior knowledge (e.g., the presence of a pattern where one should not exist), and comparison against a library of “known good” references. The efficacy and efficiency of human analysis is dependent upon several factors including, but not limited to, the sample size of the data, the person's attention to detail, the understanding of normal operating parameters, and the permitted deviation from those parameters before an issue becomes apparent. Conventional, computer-based analysis can be a solution to this problem in some circumstances, however these analyses are limited to the parameters with which they were programmed and may not offer significant additional benefits compared to a human-based analysis aside from being able to process a larger dataset more quickly.

### SUMMARY

Using an adaptable model based on machine learning and other applications of artificial intelligence, a more thorough analysis of a larger dataset can be performed with a greater level of precision than human or conventional computer-based analysis methods.

In one embodiment, waveforms can be sent to a remote computer system that is not in the same physical location where the data was originally captured. The result of the analysis performed by the remote computer system can be returned to the user describing both subjective and objective results.

In another embodiment, waveforms can be analyzed locally on a computer system that is in the same physical location where the data was originally captured. The result of the analysis performed by the local computer system can be returned to the user describing both subjective and objective results.

Additional features, advantages, and properties of this method according to the present application will become apparent from the detailed description.

### DETAILED DESCRIPTION

In the following detailed description, the method according to the present application in the form of on and off-highway vehicles and equipment will be described by the embodiments. It should be noted, however, that although this application specifically focuses on vehicles and equipment and their associated components, the contents of this application can also be applied across other powered equipment such as compressors, fans, motors, electronic circuitry, and other related components that are not installed within, nor a part of, any form of on or off-highway vehicles or equipment.

Modern automobiles and off-highway equipment are highly complex machines that require the proper function and orchestration of numerous interconnected control units and components.

As increasingly advanced features and capabilities become more commonplace in vehicles and equipment, additional control modules are required to receive inputs, process data, and provide outputs to relevant systems. For example, pressing a button to open or close a driver's side window may involve a control module that acts as an intermediary between the button and the electric motor that physically moves the window. The control module could be capable of ensuring certain conditions are met before activating the electric motor circuit, and interrupting the circuit when other conditions are met or cease to be met. The control module could also be capable of reporting the “pressed” or “not pressed” status of the button to other control modules that may use these parameters to set conditions upon which other outputs are dependent.

As the number of interconnected components increases, so too does the complexity, especially in terms of troubleshooting when an issue arises. Building upon the previous example using the driver's side window, it was possible at one time to troubleshoot this circuit by simply determining whether the electric motor is receiving power while the switch is pressed. This could help quickly determine whether the motor itself was the cause of a malfunction, or whether the switch or wiring was instead to blame. While this test still has validity today, a service technician must now also consider whether the relevant control module is receiving the correct input from the switch, processing the data properly, ensuring that there are no conditions being met, or not being met, that may prevent the module from activating the motor circuit, and finally that the motor circuit is indeed being actuated.

While some of the capabilities discussed above may be a feature of computerized diagnostic tools, also known as “scan tools,” developed either by vehicle manufacturers or various third parties, there is a fundamental, low-level commonality across all vehicle control systems, and their associated inputs and outputs. In common is the fact that all the involved systems utilize one or more characteristics of electrical energy, including but not limited to, the presence, absence, or modulation of one or more of the following: voltage, current, resistance, capacitance, frequency, duty cycle, et. al. By modifying these properties, in some cases thousands of times per second, interconnected components can receive inputs, communicate across local area networks, and control outputs.

The present invention relates to the analysis of waveforms captured from sensors and circuits present in the vehicle or equipment that were installed by its original manufacturer. These include, but are not limited to, crankshaft position, camshaft position, ignition coil and fuel injector actuation circuits, fuel and other pump motors, and local area networks controlling the communication between modules.

The present invention also relates to the analysis of waveforms captured from sensors that are temporarily installed or fixed on or within a vehicle or equipment for the purpose of data collection in ways that are not possible using only those sensors installed in the vehicle or equipment by its original manufacturer. For example, the use of a magnetically attached accelerometer to capture a vibration waveform.

When a digital storage oscilloscope (DSO) is connected to an electrical circuit to which a sensor is also connected, the voltage of that circuit is sampled by the DSO many times per second—sometimes up to several billion times per second depending on the capability of the hardware, however far less-capable hardware is typically required for on and off-highway vehicles and equipment. Each sampled data point is processed by a computer either within the DSO itself, or as a separate device to which the DSO is connected.

When the data points are superimposed onto a two-axis graph, wherein the “X” axis represents the magnitude of the voltage, and the “Y” axis represents time, a line can be drawn through each data point, connecting them together, and forming what's known as a “waveform.” While a waveform typically exists to serve as a more human-readable interpretation of numerous data points, drawing a line between data points can also aid in the interpolation of data that wasn't captured between two different points.

Analysis of the waveform can reveal the root cause of an issue by evaluating how the shape and size of the waveform compares to other, known-good waveforms, or to those waveforms of similar systems by the same module or sensor manufacturer. For example, if original equipment manufacturer “XYZ” has multiple models of vehicles or equipment that feature a specific Hall-Effect sensor that triggers at 4 volts, then it may be a reasonable supposition that the same-purposed sensor in a different model produced by XYZ for which no known-good waveform exists would also trigger at 4 volts.

The present invention leverages supervised and unsupervised machine learning models wherein the subjective and objective analysis of a waveform could be provided based on comparison with known-good waveforms collected from the same model of vehicle or equipment currently under test. In this scenario, when a captured and analyzed waveform is compared against a library of known-good references, a more conclusive result can typically be returned. For example, an analysis on a captured waveform might note that a camshaft position signal is not properly correlated to the crankshaft position signal as compared to the known-good reference, and could potentially indicate a variable valve timing system malfunction, or a base engine timing issue.

The present invention also leverages supervised and unsupervised machine learning models wherein the subjective and objective analysis of a waveform could be provided based on analysis of other known-good waveforms collected from other same-platform or same-manufacturer models of vehicles or equipment that are different than the model currently under test. In this scenario, a captured and analyzed waveform is not compared directly to a library of other, known-good waveforms, but is instead compared to parameters that were learned using similar equipment or vehicle models, or similar sensor types in different equipment or vehicle models. For example, an analysis on a captured waveform might note that a barometric pressure sensor does not begin to produce voltage output for several hundred milliseconds after being powered up. If there isn't a known-good reference to which this could be compared, the learning model might report that output from these sensors normally occur within several tens of milliseconds after being powered up, and that the captured waveform indicates a scenario in which the sensor installed in that vehicle or equipment may trigger one or more diagnostic trouble codes (DTCs) in a control module since the input is not being received within an expected timeframe.

As a sensor under test is sampled by a DSO, the resulting waveform relative to a known-good example would be expected to match one of the following descriptions: the captured waveform exactly or almost-exactly resembles the known-good reference indicating that the root cause of the issue likely does not lie with the sensor. This assumes that there were sufficient data points collected to ensure no intermittent signal loss or dropout was present. Another possible outcome is that the pattern and/or shape of the collected waveform resembles the known-good reference, but the frequency or magnitude of the voltage measurement is significantly different. This indicates, assuming that the test methodology is sound, that the root cause of the issue may be caused by the sensor or its associated wiring. A captured waveform may also appear to be a near-perfect mirror image of the known-good reference. In this case, it is possible that a component in the rotating system under test became unexpectedly magnetized.

The learning model as part of the present invention would be capable of recognizing these scenarios and would be further capable of providing analysis and feedback in the interest of helping to prevent the unnecessary (and ineffectual) replacement of components that would not ultimately have any impact on correcting the issue.

Although the invention has been explained in relation to its preferred embodiment, it is to be understood that many other possible modifications and variations can be made without departing from the spirit and scope of the invention.

1. A method and system for analyzing captured waveforms to diagnose or predict issues and failures in automotive and off-highway vehicle applications.

2. A method and system according to claim 1, wherein machine learning and other applications of artificial intelligence are used to perform waveform analysis.

3. A method and system according to claim 2, wherein a supervised learning model is trained against a library of known-good reference waveforms for same and similar models of automotive and off-highway equipment.

4. A method and system according to claim 2, wherein an unsupervised learning model is trained over time based on waveforms captured from same and similar models of automotive and off-highway equipment.

5. A method and system according to claim 2, wherein waveforms are captured, and then transmitted to a remote system for processing and analysis.

6. A method and system according to claim 2, wherein waveforms are captured, and then processed and analyzed locally on the same system used to capture the waveform.

7. A method and system according to claim 2, wherein the analysis of a waveform will result in either an objective result, a subjective result or both, and could include a recommended diagnostic troubleshooting direction.
